(19) United States
(12) Patent Application Publication
(10) Pub. No.: US 2026/0129990 A1
(43) Pub. Date: May 7, 2026

(54) PHOTODETECTOR AND ELECTRONIC APPARATUS

(71) Applicant: SONY SEMICONDUCTOR SOLUTIONS CORPORATION, KANAGAWA (JP)

(72) Inventor: KAZUYOSHI YAMASHITA, KANAGAWA (JP)

(21) Appl. No.: 19/117,204

(22) PCT Filed: Oct. 6, 2022
(86) PCT No.: PCT/JP2022/037482

§ 371 Date: Mar. 31, 2025

(51) Int. Cl. H10F 39/00; H10F 39/18

(52) U.S. Cl. CPC H10F 39/806; H10F 39/182; H10F 39/184; H10F 39/8053; H10F 39/8063

(57) ABSTRACT

A photodetector according to an embodiment of the present disclosure includes a first photoelectric conversion section (12) that photoelectrically converts light, a first light-guiding section (30) including a first structure (31) that has a size equal to or less than a wavelength of incident light and accepting incident light transmitted through the first photoelectric conversion section (12), and a second photoelectric conversion section (22) that photoelectrically converts infrared light incident via the first light-guiding section (30).

### TECHNICAL FIELD

The present disclosure relates to a photodetector and an electronic apparatus.

### BACKGROUND ART

There has been proposed a device including a photodiode that detects light (red light, green light, or blue light) corresponding to a specific region of a visible region of a light spectrum and a photodiode that detects light (infrared light) corresponding to an infrared region (PTL 1).

### CITATION LIST

### Patent Literature

PTL 1: Japanese Unexamined Patent Application Publication No. 2009-272620

### SUMMARY OF THE INVENTION

It is desired, for a device that detects light, to have improved sensitivity to infrared light.

It is desirable to provide a photodetector having favorable sensitivity.

A photodetector according to an embodiment of the present disclosure includes a first photoelectric conversion section that photoelectrically converts light, a first light-guiding section including a first structure that has a size equal to or less than a wavelength of incident light and accepting incident light transmitted through the first photoelectric conversion section, and a second photoelectric conversion section that photoelectrically converts infrared light incident via the first light-guiding section.

An electronic apparatus according to an embodiment of the present disclosure includes an optical system and a photodetector that receives light transmitted through the optical system. The photodetector includes a first photoelectric conversion section that photoelectrically converts light, a first light-guiding section including a first structure that has a size equal to or less than a wavelength of incident light and accepting incident light transmitted through the first photoelectric conversion section, and a second photoelectric conversion section that photoelectrically converts infrared light incident via the first light-guiding section.

### BRIEF DESCRIPTION OF THE DRAWINGS

FIG. 1 is a block diagram illustrating an example of a schematic configuration of an imaging device which is an example of a photodetector according to an embodiment of the present disclosure.

FIG. 2 is a diagram illustrating an example of a pixel section of the imaging device according to an embodiment of the present disclosure.

FIG. 3 is a diagram illustrating an example of a cross-sectional configuration of the imaging device according to an embodiment of the present disclosure.

FIG. 4A is a diagram illustrating an example of a planar configuration of the imaging device according to an embodiment of the present disclosure.

FIG. 4B is a diagram illustrating an example of a planar configuration of the imaging device according to an embodiment of the present disclosure.

FIG. 4C is a diagram illustrating an example of a planar configuration of the imaging device according to an embodiment of the present disclosure.

FIG. 5 is a diagram illustrating an example of a cross-sectional configuration of the imaging device according to an embodiment of the present disclosure.

FIG. 6 is a diagram illustrating an example of a planar configuration of the imaging device according to an embodiment of the present disclosure.

FIG. 7 is a diagram illustrating an example of a cross-sectional configuration of an imaging device according to Modification Example 1 of the present disclosure.

FIG. 8 is a diagram illustrating an example of a cross-sectional configuration of an imaging device according to Modification Example 2 of the present disclosure.

FIG. 9A is a diagram illustrating an example of a planar configuration of the imaging device according to Modification Example 2 of the present disclosure.

FIG. 9B is a diagram illustrating an example of a planar configuration of the imaging device according to Modification Example 2 of the present disclosure.

FIG. 9C is a diagram illustrating an example of a planar configuration of the imaging device according to Modification Example 2 of the present disclosure.

FIG. 10 is a diagram illustrating an example of a cross-sectional configuration of an imaging device according to Modification Example 3 of the present disclosure.

FIG. 11A is a diagram illustrating an example of a planar configuration of the imaging device according to Modification Example 3 of the present disclosure.

FIG. 11B is a diagram illustrating an example of a planar configuration of the imaging device according to Modification Example 3 of the present disclosure.

FIG. 11C is a diagram illustrating an example of a planar configuration of the imaging device according to Modification Example 3 of the present disclosure.

FIG. 12 is a block diagram illustrating a configuration example of an electronic apparatus including the imaging device.

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is a view depicting an example of a schematic configuration of an endoscopic surgery system.

FIG. 16 is a block diagram depicting an example of a functional configuration of a camera head and a camera control unit (CCU).

### MODES FOR CARRYING OUT THE INVENTION

Hereinafter, description is given in detail of embodiments of the present disclosure with reference to the drawings. It is to be noted that the description is given in the following order.
1. Embodiment
2. Modification Examples
3. Application Example
4. Practical Application Examples

### 1. Embodiment

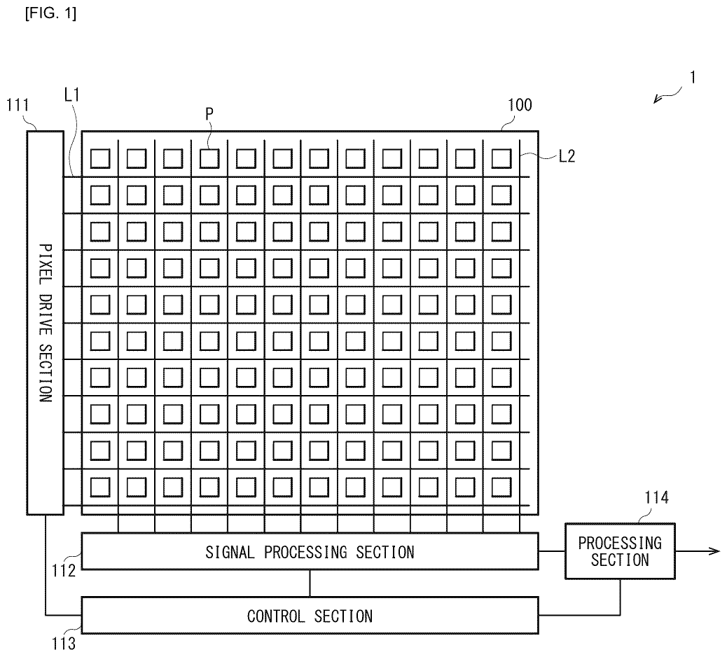

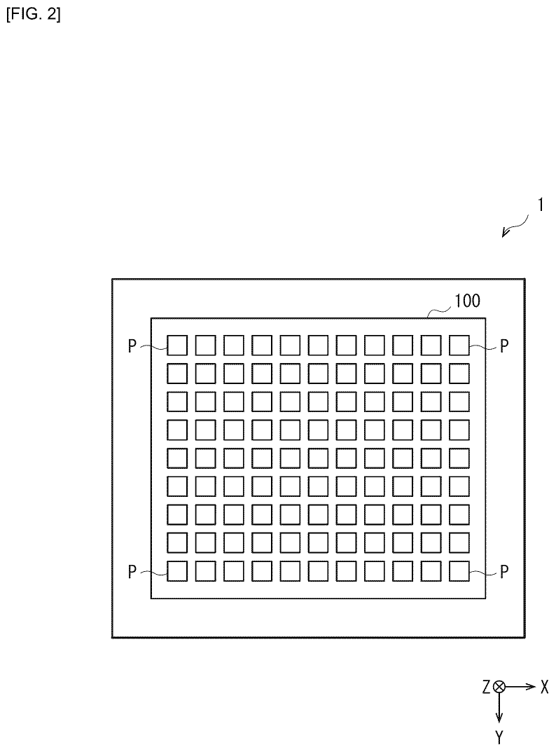

FIG. 1 is a block diagram illustrating an example of a schematic configuration of an imaging device which is an example of a photodetector according to an embodiment of the present disclosure. FIG. 2 is a diagram illustrating an example of a pixel section of the imaging device according to the embodiment. The photodetector is a device that is able to detect incident light. An imaging device 1, which is the photodetector, may receive light transmitted through an optical system and generate a signal. The imaging device 1 (photodetector) includes a plurality of pixels P each including a photoelectric conversion section, and is configured to photoelectrically convert incident light and generate a signal.

The photoelectric conversion section of each of the pixels P of the imaging device 1 is, for example, a photodiode, and is configured to be able to photoelectrically convert light. As illustrated in FIG. 2, the imaging device 1 includes, as an imaging area, a region (a pixel section 100) in which the plurality of pixels P is two-dimensionally arranged in matrix. The pixel section 100 is a pixel array in which the plurality of pixels P is arranged, and can also be referred to as a light-receiving region.

The imaging device 1 takes in incident light (image light) from a subject via the optical system (unillustrated) including an optical lens. The imaging device 1 captures an image of the subject formed by the optical lens. The imaging device 1 generates a pixel signal by photoelectrically converting the received light. The imaging device 1 is, for example, a CMOS (Complementary Metal Oxide Semiconductor) image sensor. The imaging device 1 is usable for an electronic apparatus such as a digital still camera, a video camera, or a mobile phone.

It is to be noted that, as illustrated in FIG. 2, a direction in which light from the subject is incident is defined as a Z-axis direction; a right-left direction on the sheet orthogonal to the Z-axis direction is defined as an X-axis direction; and an up-down direction on the sheet orthogonal to a Z-axis and an X-axis is defined as a Y-axis direction. In the following drawings, the arrow directions in FIG. 2 may be used, in some cases, as standards to express directions.

### Schematic Configuration of Imaging Device

As in the example illustrated in FIG. 1, the imaging device 1 includes, in a peripheral region of the pixel section 100 (pixel array), for example, a pixel drive section 111, a signal processing section 112, a control section 113, a processing section 114, and the like. In addition, the imaging device 1 is provided with a plurality of control lines L1 and a plurality of signal lines L2.

The imaging device 1 is provided with the control line L1 which is a signal line that is able to transmit a signal to control the pixel P. In the pixel section 100, for example, the plurality of control lines L1 is wired for respective pixel rows configured by the plurality of pixels P arranged in a horizontal direction (row direction). The control line L1 is configured to transmit a control signal to read a signal from the pixel P. The control line L1 can also be referred to as a pixel drive line that transmits a signal to drive the pixel P.

In addition, the imaging device 1 is provided with the signal line L2 which is a signal line that is able to convey a signal from the pixel P. In the pixel section 100, for example, the signal lines L2 are wired for respective pixel columns configured by the plurality of pixels P arranged in a vertical direction (column direction). The signal line L2 is a vertical signal line, and is configured to transmit a signal outputted from the pixel P.

The pixel drive section 111 is configured by a shift register, an address decoder, and the like. The pixel drive section 111 is configured to be able to drive each of the pixels P of the pixel section 100. The pixel drive section 111 generates a signal for controlling the pixel P, and outputs the generated signal to each of the pixels P of the pixel section 100 via the control line L1.

The pixel drive section 111 generates, for example, a signal to control a transfer transistor of the pixel P, a signal to control a reset transistor, and other signals, and supplies the generated signals to each of the pixels P by the control line L1. The pixel drive section 111 may perform a control to read a pixel signal from each of the pixels P. The pixel drive section 111 can also be referred to as a pixel control section configured to be able to control each of the pixels P.

The signal processing section 112 is configured to be able to execute signal processing on an inputted pixel signal. The signal processing section 112 includes, for example, a load circuit part, an AD (Analog Digital) conversion part, a horizontal selection switch, and the like. The signal selectively scanned by the pixel drive section 111 and outputted from each of the pixels P is inputted to the signal processing section 112 via the signal line L2. The signal processing section 112 performs signal processing such as CDS (Correlated Double Sampling: correlated double sampling) and AD conversion of a signal of the pixel P. The signal of each of the pixels P transmitted through each of the signal lines L2 is subjected to signal processing by the signal processing section 112, and is outputted to the processing section 114.

The processing section 114 is configured to be able to execute signal processing on an inputted signal. The processing section 114 is configured by, for example, a circuit that performs various types of signal processing on a pixel signal. The processing section 114 may include a processor and a memory. The processing section 114 performs signal processing on the pixel signal inputted from the signal processing section 112, and outputs the processed pixel signal. The processing section 114 may perform, for example, various types of signal processing such as noise reduction processing or gradation correction processing.

The control section 113 is configured to be able to control each section of the imaging device 1. The control section 113 may receive a clock applied from the outside, data commanding an operation mode, or the like, and output data such as internal information on the imaging device 1. The control section 113 includes a timing generator configured to be able to generate various timing signals. The control section 113 controls driving of peripheral circuits such as the pixel drive section 111 and the signal processing section 112 on the basis of the various timing signals (pulse signals, clock signals, etc.) generated by the timing generator. It is to be noted that the control section 113 and the processing section 114 may be integrally configured.

The pixel drive section 111, the signal processing section 112, the control section 113, the processing section 114, and the like may be provided in one semiconductor substrate, or may be provided separately in a plurality of semiconductor substrates. The imaging device 1 may have a structure (stacked structure) configured by stacking a plurality of substrates.

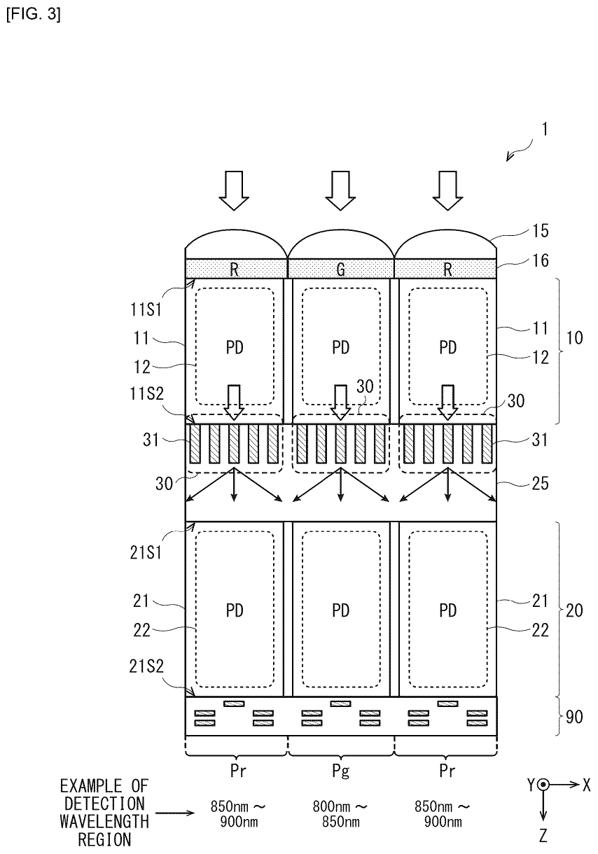

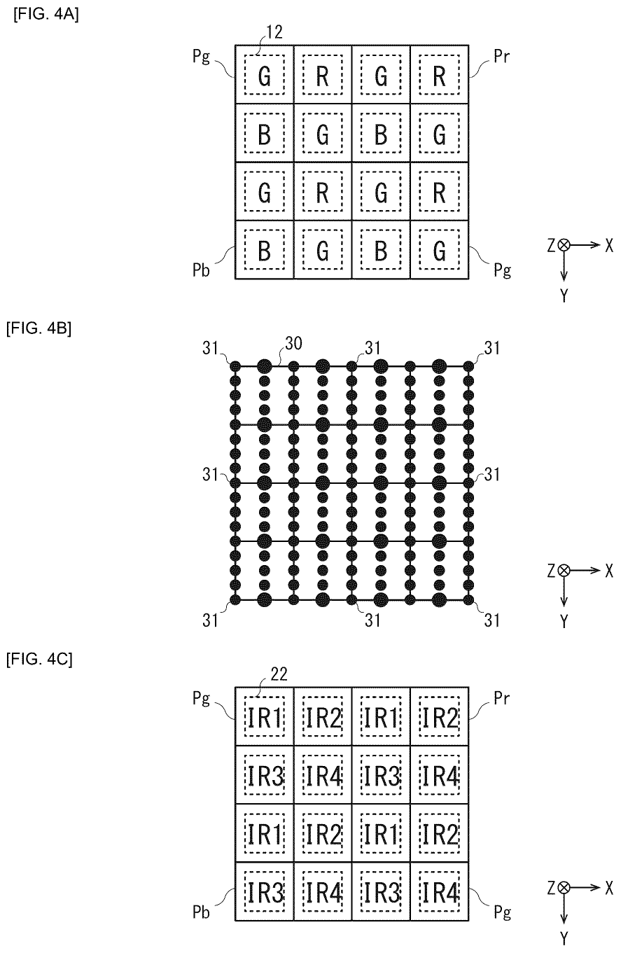

FIG. 3 is a diagram illustrating an example of a cross-sectional configuration of the imaging device according to the embodiment. FIGS. 4A to 4C are each a diagram illustrating an example of a planar configuration of the imaging device according to the embodiment. As illustrated in FIG. 3, the imaging device 1 includes a first light receiver 10, a second light receiver 20, and a light-guiding section 30. FIG. 4A illustrates an example of a planar configuration of the first light receiver 10, and FIG. 4B illustrates an example of a planar configuration of the light-guiding section 30. In addition, FIG. 4C illustrates an example of a planar configuration of the second light receiver 20.

As illustrated in FIG. 3, the imaging device 1 has a configuration in which, for example, a lens section 15, a color filter 16, the first light receiver 10, a transparent layer 25, the light-guiding section 30, the second light receiver 20, and a multilayer wiring layer 90 are stacked in the Z-axis direction. The pixel P includes a first photoelectric conversion section 12 and a second photoelectric conversion section 22. As in the example illustrated in FIG. 3, the pixel P has a structure in which the first photoelectric conversion section 12 and the second photoelectric conversion section 22 are stacked.

The first light receiver 10 illustrated in FIG. 3 includes a first substrate 11 having a first surface 11S1 and a second surface 11S2 opposed to each other. The lens section 15 and the color filter 16 are provided on a side of the first surface 11S1 of the first substrate 11. The lens section 15 and the color filter 16 are provided on a side on which light from the optical system is incident. The light-guiding section 30 is provided on a side of the second surface 11S2 of the first substrate 11.

The first substrate 11 is configured by a semiconductor substrate, e.g., a silicon substrate. The first light receiver 10 is provided with a plurality of first photoelectric conversion sections 12 along the first surface 11S1 and the second surface 11S2 of the first substrate 11. For example, the plurality of first photoelectric conversion sections 12 is formed to be embedded in the first substrate 11.

The first photoelectric conversion section 12 is configured to be able to generate electric charge by photoelectric conversion. The first photoelectric conversion section 12 is a photodiode (PD), and converts incident light into electric charge. The first photoelectric conversion section 12 is configured to receive visible light and generate electric charge. The first photoelectric conversion section 12 performs photoelectric conversion to generate electric charge corresponding to a received light amount. The first light receiver 10 (or the first substrate 11) can also be referred to as a first photodiode layer.

The second light receiver 20 includes a second substrate 21 having a first surface 21S1 and a second surface 21S2 opposed to each other. The transparent layer 25 is provided on a side of the first surface 21S1 of the second substrate 21, and the multilayer wiring layer 90 is provided on a side of the second surface 21S2 of the second substrate 21. The multilayer wiring layer 90 is provided on a side opposite to the light incident side.

The second substrate 21 is configured by a semiconductor substrate. The second light receiver 20 is provided with a plurality of second photoelectric conversion sections 22 along the first surface 21S1 and the second surface 21S2 of the second substrate 21. For example, the plurality of second photoelectric conversion sections 22 is formed to be embedded in the second substrate 21.

The second photoelectric conversion section 22 is configured to be able to generate electric charge by photoelectric conversion. The second photoelectric conversion section 22 is a photodiode (PD), and converts incident light into electric charge. The second photoelectric conversion section 22 is configured to receive infrared light and generate electric charge. The second photoelectric conversion section 22 is configured using, for example, a material such as Si, Ge, InGaAs, or InP. The second photoelectric conversion section 22 performs photoelectric conversion to generate electric charge corresponding to a received light amount. The second light receiver 20 (or the second substrate 21) can also be referred to as a second photodiode layer.

The multilayer wiring layer 90 has a configuration in which, for example, a plurality of wiring layers is stacked with an interlayer insulating layer interposed therebetween. The wiring layer of the multilayer wiring layer 90 is formed using, for example, aluminum (Al), copper (Cu), or the like. The wiring layer may be formed using polysilicon (Poly-Si). The interlayer insulating layer is formed using, for example, silicon oxide (SiOx), silicon nitride (SiNx), silicon oxynitride (SiOxNy), or the like.

The second substrate 21 and the multilayer wiring layer 90 are provided with a readout circuit (unillustrated) configured to be able to output a pixel signal based on the electric charge generated by the first photoelectric conversion section 12 or the second photoelectric conversion section 22. In addition, in the second substrate 21 and the multilayer wiring layer 90, there may also be formed, for example, the pixel drive section 111, the signal processing section 112, the control section 113, and the processing section 114, which are described above.

The readout circuit of the pixel P includes, for example, a transfer transistor, a floating diffusion (FD), a reset transistor, an amplification transistor, and the like. The pixel P includes, for example, a first readout circuit and a second readout circuit. The first readout circuit reads a pixel signal based on the electric charge photoelectrically converted by the first photoelectric conversion section 12. The second readout circuit reads a pixel signal based on the electric charge photoelectrically converted by the second photoelectric conversion section 22.

The first readout circuit is configured to be able to read the pixel signal based on the electric charge converted by the first photoelectric conversion section 12 to the signal line L2 which is the vertical signal line described above. In addition, the second readout circuit is configured to be able to read the pixel signal based on the electric charge converted by the second photoelectric conversion section 22 to the signal line L2.

The pixel drive section 111 (see FIG. 1) controls the readout circuit of each of the pixels P to thereby cause a pixel signal to be outputted from each of the pixels P to the signal line L2. The pixel drive section 111 may perform a control to read the pixel signal of each of the pixels P to the signal line L2. It is to be noted that the pixel drive section 111 and the control section 113 can also be collectively referred to as the pixel control section.

The lens section 15 guides light incident from above to a side of the first light receiver 10. The lens section 15 is an optical member also called an on-chip lens. The lens section 15 is provided above the color filter 16, for example, for each of the pixels P or for every plurality of pixels P. Light from a subject is incident on the lens section 15 via an optical system such as an imaging lens. The first photoelectric conversion section 12 photoelectrically converts visible light incident via the lens section 15 and the color filter 16.

The color filter 16 is configured to selectively transmit light of a specific wavelength region of incident light. The plurality of pixels P provided in the pixel section 100 of the imaging device 1 includes a plurality of pixels Pr, a plurality of pixels Pg, and a plurality of pixels Pb. The plurality of pixels Pr is provided with the color filter 16 that transmits red (R) light. The plurality of pixels Pg is provided with the color filter 16 that transmits green (G) light. The plurality of pixels Pb is provided with the color filter 16 that transmits blue (B) light.

In the pixel section 100, the plurality of pixels Pr, the plurality of pixels Pg, and the plurality of pixels Pb are repeatedly arranged, as in the example illustrated in FIG. 4A. The pixels Pr, the pixels Pg, and the pixels Pb are arranged in accordance with a Bayer array. One pixel Pr, two pixels Pg, and one pixel Pb constitute 2×2 pixels which are repeatedly provided. The pixel Pr, the pixel Pg, and the pixel Pb generate, respectively, a pixel signal of an R component, a pixel signal of a G component, and a pixel signal of a B component. The imaging device 1 is able to obtain pixel signals of RGB.

It is to be noted that the color filter 16 provided on the pixel P of the pixel section 100 is not limited to the color filter of the primary color system (RGB), but may be a color filter of a complementary color system such as Cy (cyan), Mg (magenta), or Ye (yellow). In a pixel Pw that receives white (W) light to perform photoelectric conversion, the color filter 16 may not be provided. In addition, a color filter corresponding to W (white), i.e., a filter that transmits light beams of all wavelength regions of incident light may be disposed. It is to be noted that the color filter 16 may be omitted as needed.

The transparent layer 25 is a transparent layer that transmits light, and is formed by, for example, a material having a low refractive index, such as silicon oxide (SiOx) or silicon nitride (SiNx). The transparent layer 25 may be configured by another transparent materials that transmit infrared light.

The light-guiding section 30 has a structure 31, and is configured to guide incident light to a side of the second light receiver 20. Infrared light transmitted through the first photoelectric conversion section 12 is incident on the light-guiding section 30. The structure 31 is a fine (micro) structure having a size equal to or less than a predetermined wavelength of incident light, and has, for example, a size equal to or less than a wavelength of infrared light. The light-guiding section 30 is an optical member (light-guiding member) that guides (propagates) light.

As illustrated in FIGS. 3 and 4B, the structure 31 is, for example, a columnar (pillar-shaped) structure, and is provided in the transparent layer 25. As schematically illustrated in FIG. 3, a plurality of structures 31 is arranged side by side with each other on the right-left direction on the sheet (X-axis direction), with a portion of the transparent layer 25 being interposed therebetween. In the transparent layer 25, the plurality of structures 31 may be arranged at intervals equal to or less than a predetermined wavelength of incident light, e.g., at intervals equal to or less than a wavelength of infrared light.

The structure 31 has a refractive index higher than a refractive index of a surrounding medium. The medium surrounding the structure 31 is, for example, silicon oxide (SiO), air (air gap), or the like. In the example illustrated in FIGS. 3 and 4B, the structure 31 is configured by a material having a refractive index higher than a refractive index of the transparent layer 25. The structure 31 is configured by a high refractive index material, and can also be referred to as a high refractive index section. In addition, the transparent layer 25 can also be referred to as a low refractive index section.

As an example, the structure 31 is formed using amorphous silicon (a-Si), polysilicon, germanium (Ge), or the like. In addition, for example, the structure 31 may be configured by a silicon compound such as silicon nitride or silicon carbide, a metal oxide such as titanium oxide, tantalum oxide, niobium oxide, hafnium oxide, indium oxide, or tin oxide, or a composite oxide thereof. In addition, the structure 31, which is a high refractive index section, may be configured by an organic matter such as siloxane. The structure 31 may be configured using a siloxane-based resin, a styrene-based resin, an acrylic-based resin, or the like.

The light-guiding section 30 is able to cause a phase delay to incident light due to a difference between the refractive index of the structure 31 and the refractive index of the medium therearound, thus affecting a wave front. The light-guiding section 30 provides a different phase delay amount depending on the wavelength of light to thereby adjust a propagation direction of the light, thus enabling separation of the incident light into light beams of respective wavelength regions. A magnitude (size), a shape, a refractive index, and the like of each of the structures 31 are determined to allow the light beams of the respective wavelength regions included in the incident light to travel in desired directions.

The light-guiding section 30 (light-dispersing section) is a light-dispersing element being able to disperse light by utilizing a meta-material (meta-surface) technology, and can also be referred to as a splitter (color splitter). It can also be said that the imaging device 1 has a color splitter structure. The directions of the propagation of the light beams of the respective wavelengths performed by the light-guiding section 30 are adjustable by materials (optical constants) of the structure 31 and the transparent layer 25, the shapes and heights of the structures 31, the arrangement interval (gap) between the structures 31, and the like. It can also be said that the light-guiding section 30 is a region (light-dispersing region) in which the structure 31 disperses the incident light.

The light-guiding section 30 is a light-dispersing section configured to be able to disperse incident light. The light-guiding section 30 is configured to disperse infrared light having passed through the first photoelectric conversion section 12. The light-guiding section 30 provides mutually different phase delays to infrared light beams of a plurality of wavelength regions, e.g., infrared light beams of a first wavelength region to a fourth wavelength region. This enables, in the imaging device 1, the infrared light incident via the first photoelectric conversion section 12 to be dispersed into the infrared light of the first wavelength region, the infrared light of the second wavelength region, the infrared light of the third wavelength region, and the infrared light of the fourth wavelength region.

The light-guiding section 30 of one pixel Pg of the 2×2 pixels of the Bayer array is configured to guide the infrared light of the first wavelength region (e.g., 800 nm to 850 nm) of the incident infrared light to the second photoelectric conversion section 22 of that pixel Pg, for example, as schematically indicated by arrows in FIG. 3. The light-guiding section 30 of the pixel Pg is configured to guide the infrared light of the second wavelength region (e.g., 850 nm to 900 nm) of the incident infrared light to the second photoelectric conversion section 22 of the pixel Pr.

In addition, the light-guiding section 30 of the pixel Pg illustrated in FIG. 3 is configured to guide the infrared light of the third wavelength region (e.g., 900 nm to 950 nm) to the second photoelectric conversion section 22 of the pixel Pb, and is configured to guide the infrared light of the fourth wavelength region (e.g., 950 nm or more) to the second photoelectric conversion section 22 of another pixel Pr of the 2×2 pixels of the Bayer array.

The light-guiding section 30 of the pixel Pr illustrated in FIG. 3 is configured to guide the infrared light of the second wavelength region of the incident infrared light to the second photoelectric conversion section 22 of that pixel Pr, for example, as schematically indicated by arrows in FIG. 3. The light-guiding section 30 of the pixel Pr is configured to guide the infrared light of the first wavelength region to the second photoelectric conversion section 22 of the one pixel Pg of the 2×2 pixels of the Bayer array. In addition, the light-guiding section 30 of the pixel Pr is configured to propagate the infrared light of the third wavelength region to the second photoelectric conversion section 22 of the pixel Pb, and is configured to propagate the infrared light of the fourth wavelength region to the second photoelectric conversion section 22 of another pixel Pg.

For example, the light-guiding section 30 of the pixel Pb is configured to propagate the infrared light of the third wavelength region of the incident infrared light to the second photoelectric conversion section 22 of that pixel Pb. In addition, the light-guiding section 30 of the pixel Pb is configured to propagate the infrared light of the first wavelength region of the incident infrared light to the second photoelectric conversion section 22 of the one pixel Pg; is configured to propagate the infrared light of the second wavelength region to the second photoelectric conversion section 22 of the pixel Pr; and is configured to propagate the infrared light of the fourth wavelength region to the second photoelectric conversion section 22 of the other pixel Pg.

For example, the light-guiding section 30 of the other pixel Pg of the 2×2 pixels of the Bayer array is configured to propagate the infrared light of the fourth wavelength region of the incident infrared light to the second photoelectric conversion section 22 of that pixel Pg. In addition, the light-guiding section 30 of this pixel Pg is configured to propagate the infrared light of the first wavelength region of the incident infrared light to the second photoelectric conversion section 22 of the one pixel Pg of the 2×2 pixels of the Bayer array; is configured to propagate the infrared light of the second wavelength region to the second photoelectric conversion section 22 of the pixel Pr; and is configured to propagate the infrared light of the third wavelength region to the second photoelectric conversion section 22 of the pixel Pb.

In the example illustrated in FIG. 4C, the second photoelectric conversion section 22 marked with “IR1”, i.e., the second photoelectric conversion section 22 of the one pixel Pg of the 2×2 pixels of the Bayer array photoelectrically converts the infrared light of the first wavelength region (e.g., 800 nm to 850 nm) incident via the light-guiding section 30. In addition, the second photoelectric conversion section 22 marked with “IR2”, i.e., the second photoelectric conversion section 22 of the pixel Pr of the 2×2 pixels of the Bayer array photoelectrically converts the infrared light of the second wavelength region (e.g., 850 nm to 900 nm) incident via the light-guiding section 30.

The second photoelectric conversion section 22 marked with “IR3”, i.e., the second photoelectric conversion section 22 of the pixel Pb of the 2×2 pixels of the Bayer array photoelectrically converts the infrared light of the third wavelength region (e.g., 900 nm to 950 nm) incident via the light-guiding section 30. In addition, the second photoelectric conversion section 22 marked with “IR4”, i.e., the second photoelectric conversion section 22 of the other pixel Pg of the 2×2 pixels of the Bayer array photoelectrically converts the infrared light of the fourth wavelength region (e.g., 950 nm or more) incident via the light-guiding section 30.

Thus, in the imaging device 1, the second photoelectric conversion section 22 marked with “IR1” may receive and photoelectrically convert the infrared light of the first wavelength region to generate electric charge corresponding to a received light amount. The second photoelectric conversion section 22 marked with “IR2” may receive and photoelectrically convert the infrared light of the second wavelength region to generate electric charge corresponding to a received light amount. The second photoelectric conversion section 22 marked with “IR3” may receive and photoelectrically convert the infrared light of the third wavelength region to generate electric charge corresponding to a received light amount.

In addition, the second photoelectric conversion section 22 marked with “IR4” may receive and photoelectrically convert the infrared light of the fourth wavelength region to generate electric charge corresponding to a received light amount. As described above, each of the pixels P marked with “IR1” to “IR4” is also an IR pixel, and may receive and photoelectrically convert infrared light to generate a pixel signal. It is therefore possible for the imaging device 1 to obtain a pixel signal of an IR component for each wavelength region.

Thus, it is possible, in the imaging device 1, to concurrently obtain a pixel signal corresponding to a light amount of visible light and a pixel signal corresponding to a light amount of infrared light for each wavelength region. It is possible for the imaging device 1 to generate a visible image using pixel signals of RGB obtained by photoelectric conversion performed by the first photoelectric conversion section 12.

In addition, it is possible for the imaging device 1 to generate an infrared image (IR image) using a pixel signal obtained by photoelectric conversion performed by the second photoelectric conversion section 22. In addition, it is possible, in the present embodiment, to acquire an infrared image for each of the wavelength regions of the infrared light beams. It is possible to achieve multi-spectralization for an infrared light region.

As described above, the imaging device 1 is provided with the light-guiding section 30 including the structure 31 described above between the first photoelectric conversion section 12 and the second photoelectric conversion section 22. It is possible to appropriately guide infrared light transmitted through the first photoelectric conversion section 12 to the second photoelectric conversion section 22. It is therefore possible for the imaging device 1 to suppress a decrease in sensitivity to infrared light.

In the present embodiment, it is possible to allow the light-guiding section 30, which is configured using a high refractive index material, to condense infrared light to the second photoelectric conversion section 22 from a peripheral pixel of the pixel P. It is possible for the second photoelectric conversion section 22 of the pixel P to efficiently receive and photoelectrically convert infrared light to generate electric charge corresponding to a received light amount. In addition, it is possible to suppress a decrease in the resolution of RGB, as compared with a case where a photoelectric conversion section that photoelectrically converts infrared light is provided to replace some of the plurality of first photoelectric conversion sections 12 that photoelectrically converts visible light. In addition, it is possible to reduce occurrence of color mixture.

In addition, in the present embodiment, the light-guiding section 30 is provided that disperses infrared light depending on a wavelength. It is therefore possible to concurrently obtain images with distinguished IR wavelengths (e.g., the above-described infrared images for the respective first to fourth wavelength regions). It is possible to achieve a photodetector that detects infrared light beams (multi-spectrum) of a plurality of wavelength bands. In addition, it is possible to suppress a decrease in IR sensitivity, as compared with a case where spectroscopy is performed using a filter (e.g., a band-pass filter) that absorbs IR light. It is possible to improve quantum efficiency (QE).

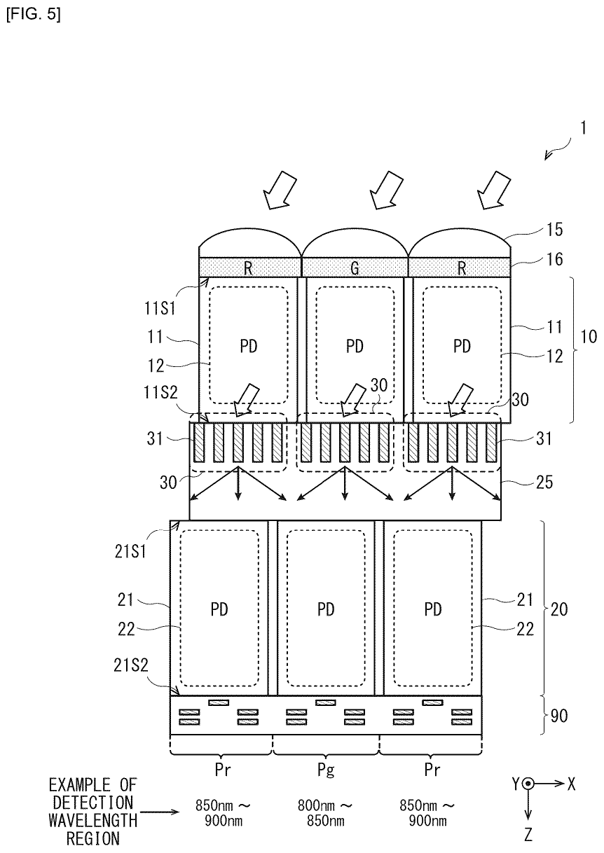

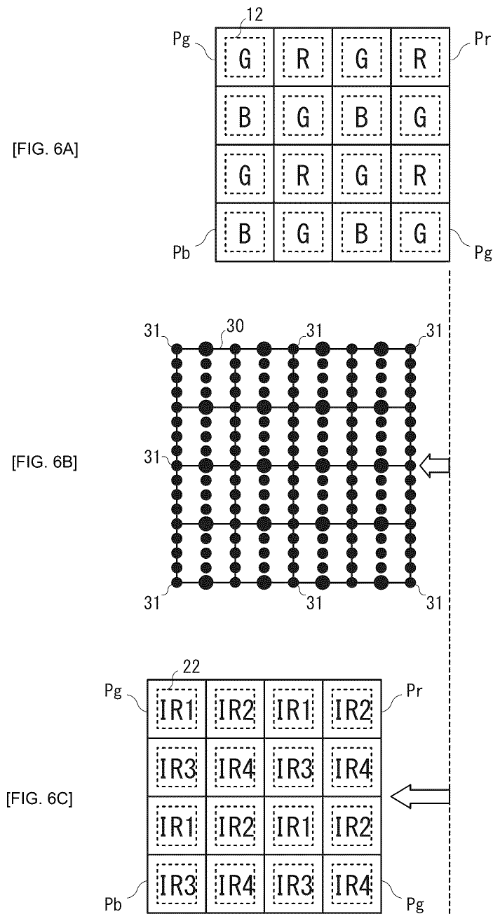

FIG. 5 illustrates an example of a cross-sectional configuration of the imaging device 1 in a region where a distance from the center of the pixel section 100 (pixel array), i.e., an image height is high. (A) to (C) of FIG. 6 each illustrate an example of a planar configuration of the first light receiver 10, the light-guiding section 30, and the second light receiver 20 in the region where the image height is high.

Light from an optical lens is incident substantially perpendicularly on the middle part of the pixel section 100 of the imaging device 1. Meanwhile, light is obliquely incident on a peripheral part positioned outside the middle part, i.e., a region distant from the middle of the pixel section 100, as in the example indicated by open white arrows in FIG. 5. Therefore, the imaging device 1 is configured to allow positions of the lens section 15, the color filter 16, the first photoelectric conversion section 12, the light-guiding section 30, the second photoelectric conversion section 22, and the like, in each of the pixels P to vary depending on the distance from the center of the pixel section 100, i.e., depending on the image height.

As illustrated in FIG. 5, the lens section 15, the color filter 16, the first photoelectric conversion section 12, and the light-guiding section 30 of the pixel P (the pixels Pr and Pg in FIG. 5) are arranged to be shifted to a side of the middle of the pixel section 100 from the second photoelectric conversion section 22 of that pixel P. It can also be said that the light-guiding section 30 and the second photoelectric conversion section 22 are shifted to a side of an end of the pixel section 100 from the lens section 15, the color filter 16, and the first photoelectric conversion section 12 of That Pixel P.

In the example illustrated in FIG. 5, the lens section 15, the color filter 16, the first photoelectric conversion section 12, and the light-guiding section 30 are provided to be shifted rightward on the sheet from the second photoelectric conversion section 22. It can also be said that the light-guiding section 30 and the second photoelectric conversion section 22 are shifted leftward on the sheet from the lens section 15, the color filter 16, and the first photoelectric conversion section 12.

It is to be noted that, in the middle region of the pixel section 100 (pixel array), the pixels P are configured, for example, as illustrated in FIGS. 3 and 4A to 4C described above. In the pixel P at the middle of the pixel section 100, respective center positions of the lens section 15, the color filter 16, the first photoelectric conversion section 12, the light-guiding section 30, and the second photoelectric conversion section 22 are substantially coincident with one another, as in the example illustrated in FIG. 3.

As described above, in the imaging device 1, the respective positions of the lens section 15, the color filter 16, the first photoelectric conversion section 12, the light-guiding section 30, the second photoelectric conversion section 22, and the like are adjusted depending on the image height, thus making it possible to appropriately perform pupil correction. It is possible to suppress a decrease in an amount of light incident on the first photoelectric conversion section 12 and the second photoelectric conversion section 22 and to prevent a decrease in sensitivity to incident light. Even in a case where light is incident obliquely, it is possible to appropriately propagate the incident light to the second photoelectric conversion section 22.

It is possible to manufacture the above-described imaging device 1 using a typical semiconductor process. For example, the first substrate 11, in which the first photoelectric conversion section 12, the light-guiding section 30, and the transparent layer 25 are formed, and the second substrate 21, in which the second photoelectric conversion section 22 is formed, are attached to each other, and then the color filter 16, the lens section 15, and the like are formed thereon, thereby enabling the imaging device 1 illustrated in FIG. 3 or other drawings to be manufactured. It is to be noted that this manufacturing method is merely an example, and another manufacturing method may be adopted.

### Workings and Effects

The photodetector according to the present embodiment includes a first photoelectric conversion section (first photoelectric conversion section 12) that photoelectrically converts light, a first light-guiding section (light-guiding section 30) including a first structure (structure 31) that has a size equal to or less than a wavelength of incident light and accepting incident light transmitted through the first photoelectric conversion section, and a second photoelectric conversion section (second photoelectric conversion section 22) that photoelectrically converts infrared light incident via the first light-guiding section.

The photodetector (imaging device 1) according to the present embodiment is provided with the light-guiding section 30 that accepts incident light transmitted through the first photoelectric conversion section 12 and the second photoelectric conversion section 22 that photoelectrically converts infrared light incident via the light-guiding section 30. It is therefore possible to suppress a decrease in the sensitivity to infrared light. It becomes possible to achieve a photodetector having favorable detection performance.

The photodetector according to the present embodiment is provided, next to the second photoelectric conversion section (e.g., the second photoelectric conversion section 22 of the one pixel Pg of the 2×2 pixels of the Bayer array), with a third photoelectric conversion section (e.g., the second photoelectric conversion section 22 of the pixel Pr) that photoelectrically converts infrared light incident via the first light-guiding section. In addition, the photodetector includes a fourth photoelectric conversion section (e.g., the second photoelectric conversion section 22 of the pixel Pb) and a fifth photoelectric conversion section (e.g., the second photoelectric conversion section 22 of the other pixel Pg of the 2×2 pixels of the Bayer array). The second photoelectric conversion section, the third photoelectric conversion section, the fourth photoelectric conversion section, and the fifth photoelectric conversion section receive and photoelectrically convert respective infrared light beams having wavelengths different from one another.

It is possible, in the present embodiment, to obtain respective pixel signals of IR components in the first wavelength region to the fourth wavelength region. It is possible to achieve a photodetector that detects infrared light beams (multi-spectrum) of the plurality of wavelength bands. It becomes possible to acquire infrared images for respective wavelength regions of infrared light beams.

Next, description is given of modification examples of the present disclosure. Hereinafter, components similar to those of the foregoing embodiment are denoted by the same reference numerals, and descriptions thereof are omitted as appropriate.

### 2. Modification Examples

### 2-1. Modification Example 1

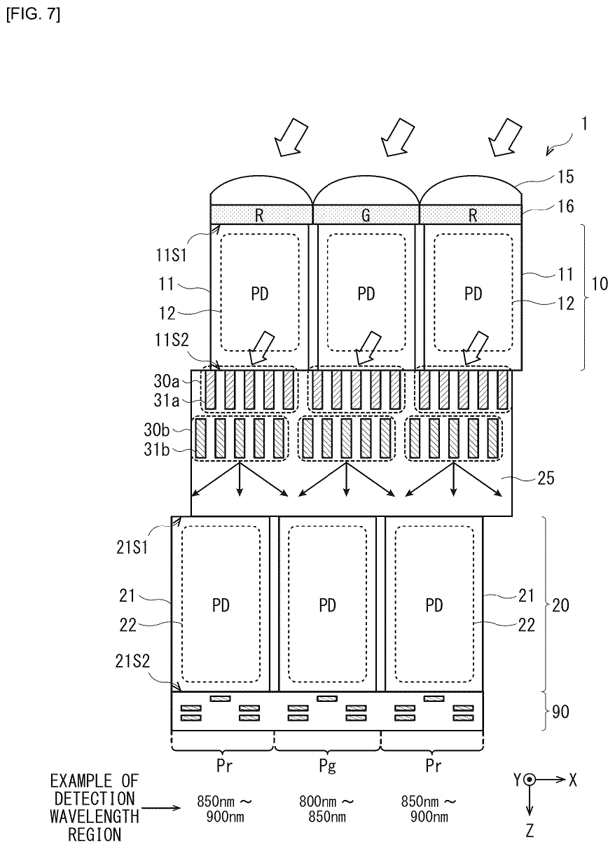

FIG. 7 is a diagram illustrating an example of a cross-sectional configuration of an imaging device according to Modification Example 1 of the present disclosure. FIG. 7 illustrates an example of a cross-sectional configuration of the pixel P in a region where the image height is high. As in the example illustrated in FIG. 7, the imaging device 1 may have a structure in which a light-guiding section 30a including a structure 31a and a light-guiding section 30b including a structure 31b are stacked. The second photoelectric conversion section 22 may photoelectrically convert infrared light incident via the light-guiding section 30a and the light-guiding section 30b to generate electric charge. As in the example illustrated in FIG. 7, the light-guiding section 30a including the structure 31a and the light-guiding section 30b including the structure 31b may be arranged to be shifted from each other depending on the image height. In the present modification example, the two-layered light-guiding sections enable obliquely incident light to be appropriately guided.

The structure 31a of the light-guiding section 30a and the structure 31b of the light-guiding section 30b are each a fine structure having a size equal to or less than a predetermined wavelength of incident light, and each have, for example, a size equal to or less than a wavelength of infrared light. The structure 31a of the light-guiding section 30a and the structure 31b of the light-guiding section 30b may be formed, for example, to have sizes, shapes, and the like, which are different from each other. In this case, it is possible to effectively suppress a decrease in spectral characteristics at the time of the obliquely incident light. It is to be noted that the light-guiding section 30a and the light-guiding section 30b may be configured using the same material or may be configured using different materials.

### 2-2. Modification Example 2

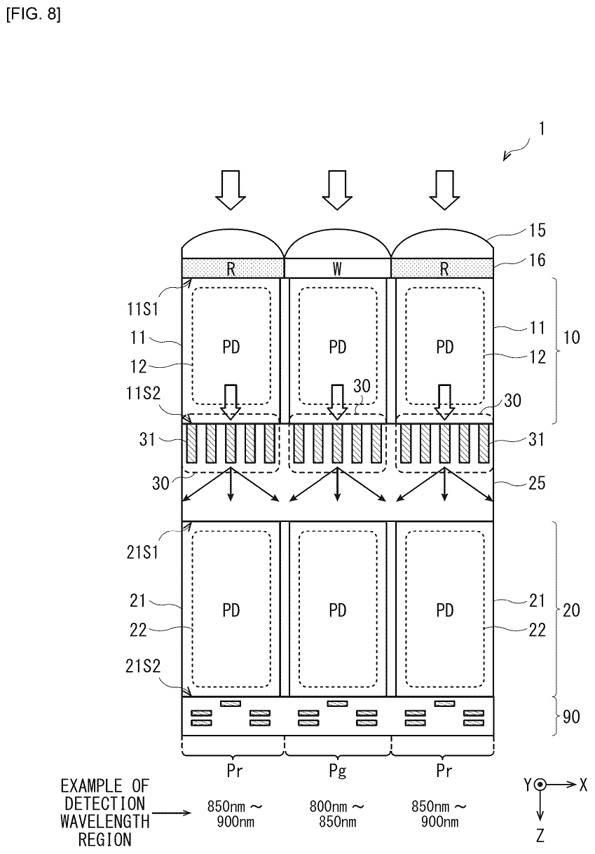

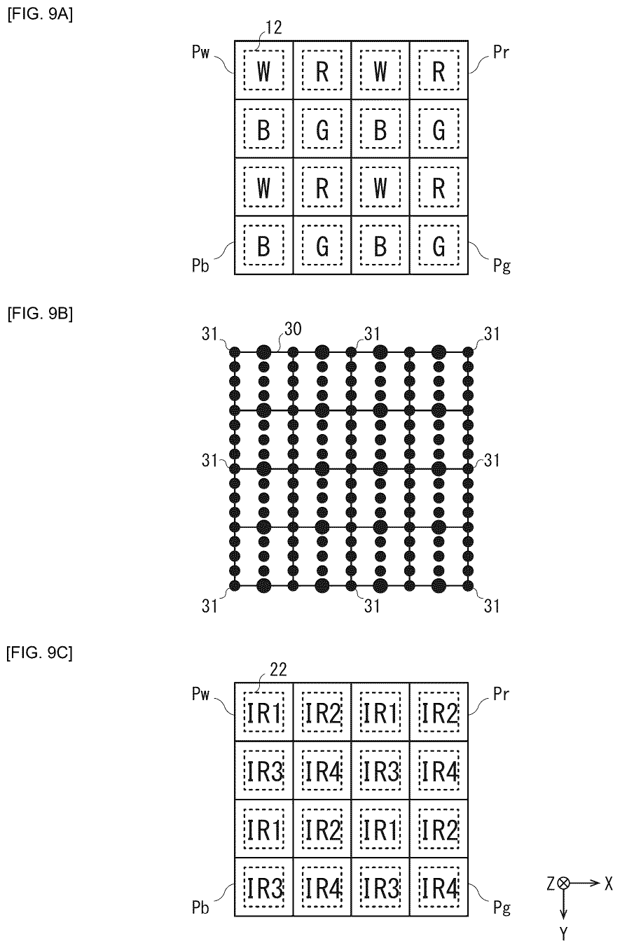

FIG. 8 is a diagram illustrating an example of a cross-sectional configuration of an imaging device according to Modification Example 2. FIGS. 9A to 9C are each a diagram illustrating an example of a planar configuration of the imaging device according to Modification Example 2. As in the example illustrated in FIGS. 8 and 9A to 9C, the imaging device 1 may include the pixel Pw that receives and photoelectrically converts white (W) light. It is possible, in the imaging device 1 according to the present modification example, to obtain a luminance signal using a pixel signal of the pixel Pw. In addition, it is possible, also in the present modification example, to obtain effects similar to those of the foregoing embodiment.

### 2-3. Modification Example 3

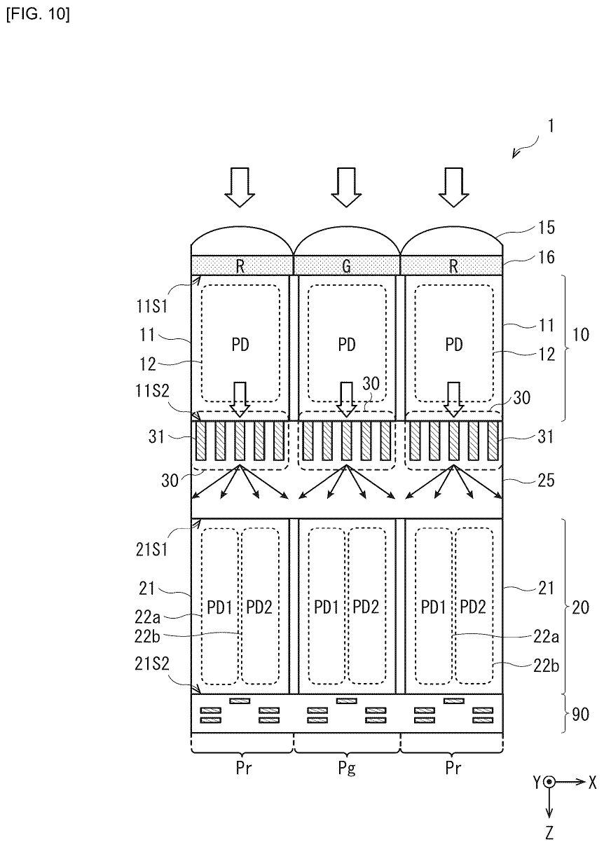

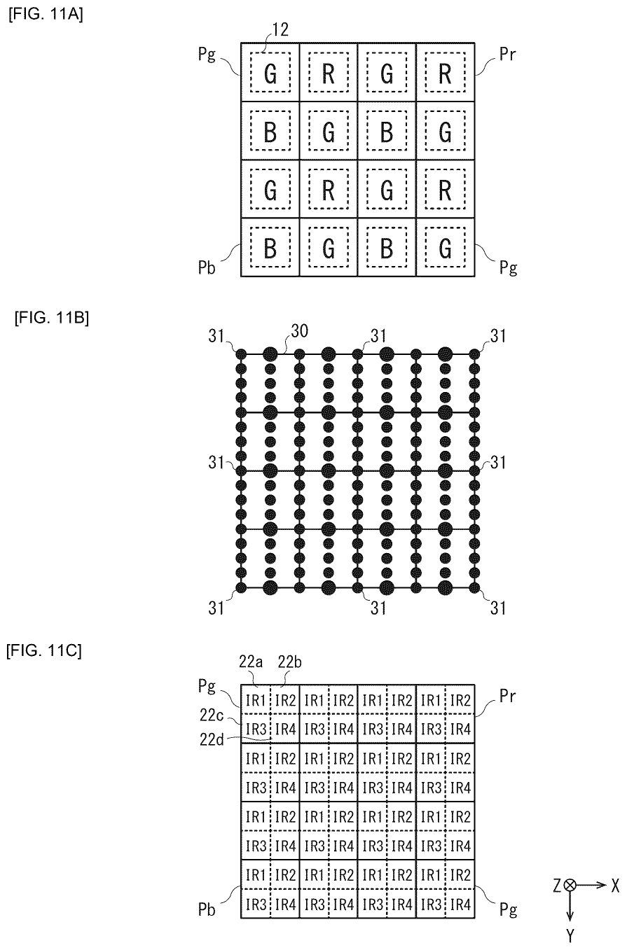

The description has been given, in the foregoing embodiment, of the example in which one second photoelectric conversion section 22 is provided for each of the pixels P. However, the plurality of second photoelectric conversion sections 22 may be provided for each of the pixels P. FIG. 10 is a diagram illustrating an example of a cross-sectional configuration of an imaging device according to Modification Example 3. FIGS. 11A to 11C are each a diagram illustrating an example of a planar configuration of the imaging device according to Modification Example 3.

As illustrated in FIGS. 10 and 11C, or other drawings, the second photoelectric conversion section 22 may be provided in a 2×2 unit. In the example illustrated in FIG. 11C, four second photoelectric conversion sections 22a to 22d marked with “IR1” to “IR4” are arranged for each of the pixels P. The second photoelectric conversion sections 22a to 22d are provided for one lens section 15. The second photoelectric conversion sections 22a to 22d may receive and photoelectrically convert infrared light beams of wavelength regions different from one another to generate electric charge. It is possible to obtain respective pixel signals of IR components in the first wavelength region to the fourth wavelength region.

It is possible, in the present modification example, to obtain a pixel signal (or an image) having high sensitivity to infrared light as well as high wavelength resolution and high spatial resolution. In addition, in the same manner as the case of the foregoing embodiment, it is possible to achieve multi-spectralization in a wavelength region of infrared light, while avoiding a decrease in the resolution of RGB.

### 2-4. Modification Example 4

The description has been given, in the foregoing embodiment and modification examples, of the configuration example of the light-guiding section 30 including the structure 31. The shape of the structure 31 of the light-guiding section 30 is not limited to the above-described example. The shape of the structure 31 can be changed as appropriate, and may be, for example, a shape of a quadrangle in a plan view. The shape of the structure 31 may be a polygon, an ellipse, a cross, or another shape.

It is to be noted that, instead of at least one of the lens section 15 or the color filter 16, or in addition thereto, a light-guiding section configured using a structure may be provided above the first photoelectric conversion section 12. This structure is a columnar fine structure, for example, in the same manner as the structure 31 of the light-guiding section 30. It is to be noted that the shape of the structure can be changed as appropriate, and may be a polygon or another shape.

### 3. Application Example

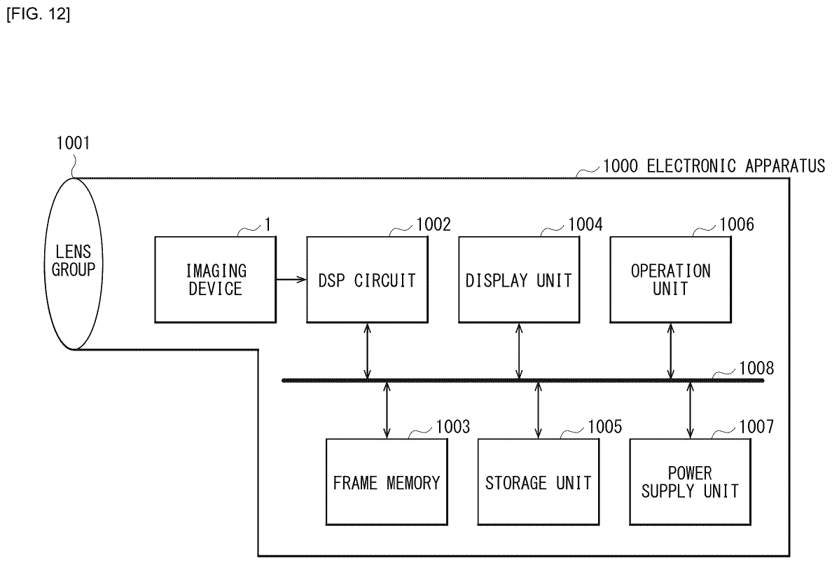

The above-described imaging device 1 or the like is applicable, for example, to any type of electronic apparatus with an imaging function including a camera system such as a digital still camera or a video camera, a mobile phone having an imaging function, and the like. FIG. 12 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

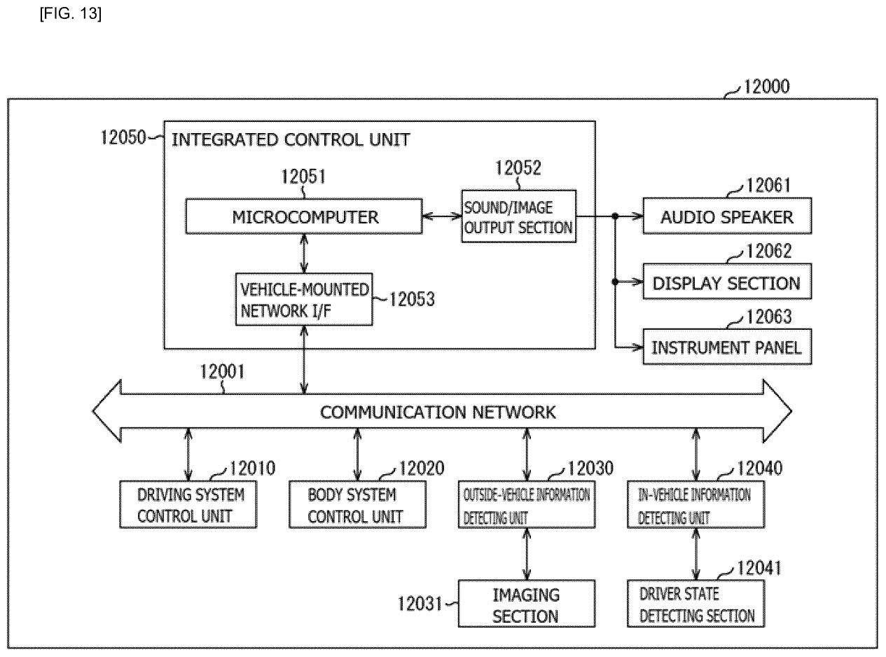

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

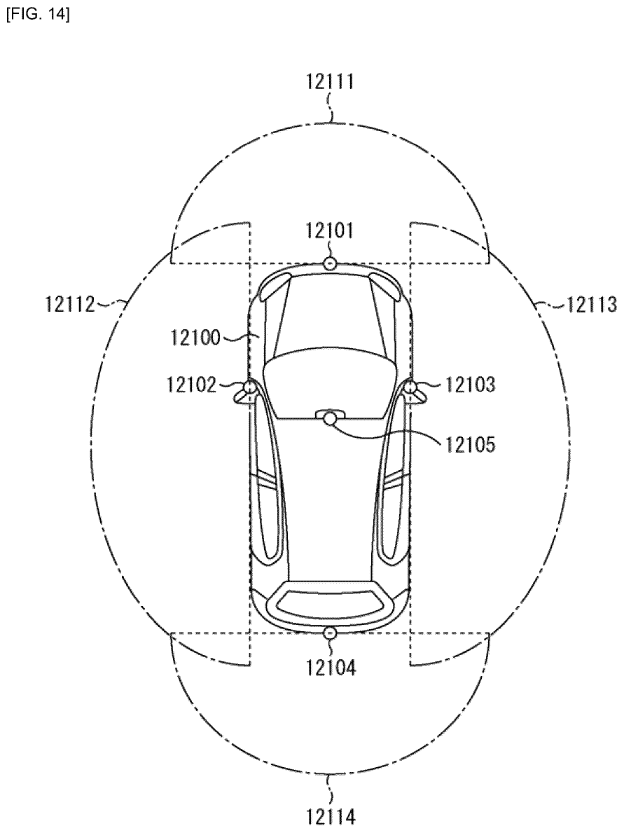

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition, thus making it possible to perform highly accurate control utilizing the photographed image in the mobile body control system.

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

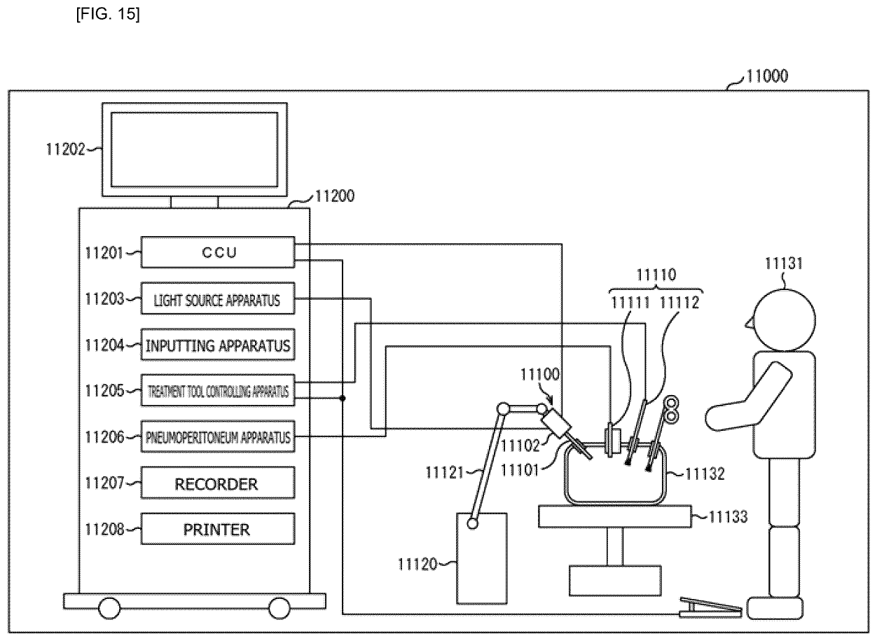

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

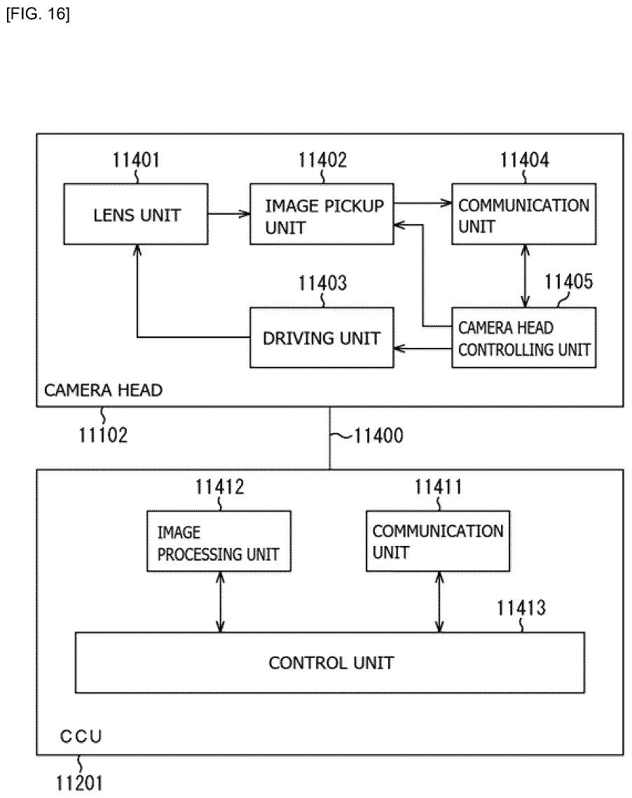

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 makes it possible to cause the image pickup unit 11402 to have higher sensitivity and thus to provide the endoscope 11100 having high definition.

Although the description has been given hereinabove of the present disclosure with reference to the embodiment, the modification examples, the application example, and the practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate.

In the foregoing embodiment and the like, the imaging device has been exemplified for description. However, it is sufficient for the photodetector of the present disclosure to be, for example, a device that receives incident light and converts the light into electric charge. A signal to be outputted may be a signal of image information or a signal of information on a measured distance. The photodetector (imaging device) is applicable to an image sensor, a distance measurement sensor, or the like.

The photodetector according to the present disclosure is also applicable as a distance measurement sensor that enables distance measurement of a TOF (Time Of Flight) method. The photodetector (imaging device) is also applicable as a sensor that is able to detect an event, e.g., an event-driven sensor (referred to as EVS (Event Vision Sensor), EDS (Event Driven Sensor), DVS (Dynamic Vision Sensor), etc.).

The photodetector according to an embodiment of the present disclosure includes a first photoelectric conversion section that photoelectrically converts light, a first light-guiding section including a first structure that has a size equal to or less than a wavelength of incident light and accepting incident light transmitted through the first photoelectric conversion section, and a second photoelectric conversion section that photoelectrically converts infrared light incident via the first light-guiding section. It is therefore possible to suppress a decrease in sensitivity to infrared light. It becomes possible to achieve a photodetector having favorable detection performance.

It is to be noted that the effects described herein are merely exemplary and are not limited to the description, and may further include other effects. In addition, the present disclosure may also have the following configurations.

(1)

A photodetector including:
a first photoelectric conversion section that photoelectrically converts light;
a first light-guiding section including a first structure having a size equal to or less than a wavelength of incident light, the first light-guiding section accepting incident light transmitted through the first photoelectric conversion section; and
a second photoelectric conversion section that photoelectrically converts infrared light incident via the first light-guiding section.
   (2)

The photodetector according to (1), including a third photoelectric conversion section provided next to the second photoelectric conversion section, the third photoelectric conversion section photoelectrically converting infrared light incident via the first light-guiding section.

(3)

The photodetector according to (2), in which
the second photoelectric conversion section photoelectrically converts infrared light of a first wavelength incident via the first light-guiding section, and
the third photoelectric conversion section photoelectrically converts infrared light of a second wavelength that is different from the first wavelength incident via the first light-guiding section.
   (4)

The photodetector according to (2) or (3), in which the first light-guiding section is provided between the first photoelectric conversion section and the second photoelectric conversion section, the first light-guiding section dispersing light transmitted through the first photoelectric conversion section.

(5)

The photodetector according to any one of (2) to (4), in which the first light-guiding section guides infrared light of the first wavelength, of incident light, to a side of the second photoelectric conversion section, and guides infrared light of the second wavelength that is different from the first wavelength to a side of the third photoelectric conversion section.

(6)

The photodetector according to any one of (2) to (5), including a fourth photoelectric conversion section that photoelectrically converts infrared light incident via the first light-guiding section, in which
the second photoelectric conversion section, the third photoelectric conversion section, and the fourth photoelectric conversion section receive and photoelectrically convert infrared light beams of wavelengths that are different from one another.
   (7)

The photodetector according to (6), including a fifth photoelectric conversion section that photoelectrically converts infrared light incident via the first light-guiding section, in which
the second photoelectric conversion section, the third photoelectric conversion section, the fourth photoelectric conversion section, and the fifth photoelectric conversion section receive and photoelectrically convert infrared light beams of wavelengths that are different from one another.
   (8)

The photodetector according to any one of (2) to (7), including the fourth photoelectric conversion section that photoelectrically converts infrared light incident via the first light-guiding section, in which
the first light-guiding section guides infrared light of the first wavelength, of incident light, to the side of the second photoelectric conversion section, guides infrared light of the second wavelength to the side of the third photoelectric conversion section, and guides infrared light of a third wavelength to a side of the fourth photoelectric conversion section.
   (9)

The photodetector according to (8), including the fifth photoelectric conversion section that photoelectrically converts infrared light incident via the first light-guiding section, in which
the first light-guiding section guides infrared light of the first wavelength, of incident light, to the side of the second photoelectric conversion section, guides infrared light of the second wavelength to the side of the third photoelectric conversion section, guides infrared light of the third wavelength to the side of the fourth photoelectric conversion section, and guides infrared light of a fourth wavelength to a side of the fifth photoelectric conversion section.
   (10)

The photodetector according to any one of (1) to (9), including a pixel array including a plurality of the first photoelectric conversion sections, in which
a distance between a center of the first photoelectric conversion section and a center of the first light-guiding section varies, depending on a distance from a center of the pixel array.
   (11)

The photodetector according to any one of (1) to (10), including the pixel array including the plurality of the first photoelectric conversion sections, in which
a distance between the center of the first light-guiding section and a center of the second photoelectric conversion section varies, depending on a distance from the center of the pixel array.
   (12)

The photodetector according to any one of (1) to (11), in which the first structure has a size equal to or less than a wavelength of infrared light.

(13)

The photodetector according to any one of (1) to (12), in which the first structure has a refractive index that is higher than a refractive index of a medium next to the first structure.

(14)

The photodetector according to any one of (1) to (13), including a second light-guiding section provided between the first photoelectric conversion section and the first light-guiding section, the second light-guiding section including a second structure having a size equal to or less than a wavelength of incident light, in which
the second photoelectric conversion section photoelectrically converts infrared light incident via the first light-guiding section and the second light-guiding section.
   (15)

The photodetector according to (14), including the pixel array including the plurality of the first photoelectric conversion sections, in which
a distance between the center of the first light-guiding section and the center of the second light-guiding section varies, depending on a distance from the center of the pixel array.
   (16)

The photodetector according to (14) or (15), in which
the second structure has a size equal to or less than a wavelength of infrared light, and
the second structure has a refractive index that is higher than a refractive index of a medium next to the second structure.
   (17)

The photodetector according to any one of (1) to (16), in which the first photoelectric conversion section photoelectrically converts visible light.

(18)

The photodetector according to any one of (2) to (17), including:
a lens on which light is incident; and
a color filter provided between the lens and the first photoelectric conversion section, in which
the first photoelectric conversion section photoelectrically converts light transmitted through the lens and the color filter.
   (19)

The photodetector according to (18), in which the second photoelectric conversion section and the third photoelectric conversion section are provided for the lens.

(20)

An electronic apparatus including:
an optical system; and
a photodetector that receives light transmitted through the optical system,
the photodetector including
   a first photoelectric conversion section that photoelectrically converts light,
   a first light-guiding section including a first structure having a size equal to or less than a wavelength of incident light, the first light-guiding section accepting incident light transmitted through the first photoelectric conversion section, and
   a second photoelectric conversion section that photoelectrically converts infrared light incident via the first light-guiding section.

It should be understood by those skilled in the art that various modifications, combinations, sub-combinations, and alterations may occur depending on design requirements and other factors insofar as they are within the scope of the appended claims or the equivalents thereof.

1. A photodetector comprising:
a first photoelectric conversion section that photoelectrically converts light;
a first light-guiding section including a first structure having a size equal to or less than a wavelength of incident light, the first light-guiding section accepting incident light transmitted through the first photoelectric conversion section; and
a second photoelectric conversion section that photoelectrically converts infrared light incident via the first light-guiding section.

2. The photodetector according to claim 1, comprising a third photoelectric conversion section provided next to the second photoelectric conversion section, the third photoelectric conversion section photoelectrically converting infrared light incident via the first light-guiding section.

3. The photodetector according to claim 2, wherein
the second photoelectric conversion section photoelectrically converts infrared light of a first wavelength incident via the first light-guiding section, and
the third photoelectric conversion section photoelectrically converts infrared light of a second wavelength that is different from the first wavelength incident via the first light-guiding section.

4. The photodetector according to claim 2, wherein the first light-guiding section is provided between the first photoelectric conversion section and the second photoelectric conversion section, the first light-guiding section dispersing light transmitted through the first photoelectric conversion section.

5. The photodetector according to claim 2, wherein the first light-guiding section guides infrared light of a first wavelength, of incident light, to a side of the second photoelectric conversion section, and guides infrared light of a second wavelength that is different from the first wavelength to a side of the third photoelectric conversion section.

6. The photodetector according to claim 2, comprising a fourth photoelectric conversion section that photoelectrically converts infrared light incident via the first light-guiding section, wherein
the second photoelectric conversion section, the third photoelectric conversion section, and the fourth photoelectric conversion section receive and photoelectrically convert infrared light beams of wavelengths that are different from one another.

7. The photodetector according to claim 6, comprising a fifth photoelectric conversion section that photoelectrically converts infrared light incident via the first light-guiding section, wherein
the second photoelectric conversion section, the third photoelectric conversion section, the fourth photoelectric conversion section, and the fifth photoelectric conversion section receive and photoelectrically convert infrared light beams of wavelengths that are different from one another.

8. The photodetector according to claim 2, comprising a fourth photoelectric conversion section that photoelectrically converts infrared light incident via the first light-guiding section, wherein
the first light-guiding section guides infrared light of a first wavelength, of incident light, to a side of the second photoelectric conversion section, guides infrared light of a second wavelength to a side of the third photoelectric conversion section, and guides infrared light of a third wavelength to a side of the fourth photoelectric conversion section.

9. The photodetector according to claim 8, comprising a fifth photoelectric conversion section that photoelectrically converts infrared light incident via the first light-guiding section, wherein
the first light-guiding section guides infrared light of the first wavelength, of incident light, to the side of the second photoelectric conversion section, guides infrared light of the second wavelength to the side of the third photoelectric conversion section, guides infrared light of the third wavelength to the side of the fourth photoelectric conversion section, and guides infrared light of a fourth wavelength to a side of the fifth photoelectric conversion section.

10. The photodetector according to claim 1, comprising a pixel array including a plurality of the first photoelectric conversion sections, wherein
a distance between a center of the first photoelectric conversion section and a center of the first light-guiding section varies, depending on a distance from a center of the pixel array.

11. The photodetector according to claim 1, comprising a pixel array including a plurality of the first photoelectric conversion sections, wherein
a distance between a center of the first light-guiding section and a center of the second photoelectric conversion section varies, depending on a distance from a center of the pixel array.

12. The photodetector according to claim 1, wherein the first structure has a size equal to or less than a wavelength of infrared light.

13. The photodetector according to claim 1, wherein the first structure has a refractive index that is higher than a refractive index of a medium next to the first structure.

14. The photodetector according to claim 1, comprising a second light-guiding section provided between the first photoelectric conversion section and the first light-guiding section, the second light-guiding section including a second structure having a size equal to or less than a wavelength of incident light, wherein
the second photoelectric conversion section photoelectrically converts infrared light incident via the first light-guiding section and the second light-guiding section.

15. The photodetector according to claim 14, comprising a pixel array including a plurality of the first photoelectric conversion sections, wherein
a distance between a center of the first light-guiding section and a center of the second light-guiding section varies, depending on a distance from a center of the pixel array.

16. The photodetector according to claim 14, wherein
the second structure has a size equal to or less than a wavelength of infrared light, and
the second structure has a refractive index that is higher than a refractive index of a medium next to the second structure.

17. The photodetector according to claim 1, wherein the first photoelectric conversion section photoelectrically converts visible light.

18. The photodetector according to claim 2, comprising:
a lens on which light is incident; and
a color filter provided between the lens and the first photoelectric conversion section, wherein
the first photoelectric conversion section photoelectrically converts light transmitted through the lens and the color filter.

19. The photodetector according to claim 18, wherein the second photoelectric conversion section and the third photoelectric conversion section are provided for the lens.

20. An electronic apparatus comprising:
an optical system; and
a photodetector that receives light transmitted through the optical system,
the photodetector including
a first photoelectric conversion section that photoelectrically converts light,
a first light-guiding section including a first structure having a size equal to or less than a wavelength of incident light, the first light-guiding section accepting incident light transmitted through the first photoelectric conversion section, and
a second photoelectric conversion section that photoelectrically converts infrared light incident via the first light-guiding section.
